(19) United States
(12) Patent Application Publication
(10) Pub. No.: US 2024/0266473 A1
(43) Pub. Date: Aug. 8, 2024

(54) MOLYBDENUM CARRIER SUBSTRATE FOR A SURFACE-EMITTING IR-LED DEVICE

(71) Applicant: VISHAY SEMICONDUCTOR GmbH, Heilbronn (DE)

(72) Inventor: PHILIPP LEBER, Tamm (DE)

(73) Assignee: VISHAY SEMICONDUCTOR GmbH, Heilbronn (DE)

(21) Appl. No.: 18/166,267

(22) Filed: Feb. 8, 2023

(51) Int. Cl. H01L 33/40

(52) U.S. Cl. CPC H01L 33/405; H01L 2933/0016

(57) ABSTRACT

An optoelectronic semiconductor device includes a top contact and a conductive carrier including a metallic molybdenum conductive carrier substrate. A metal layer is deposited on the metallic molybdenum conductive carrier substrate. A light emitting film is disposed between the top contact, a mirror layer and the metallic molybdenum conductive carrier substrate.

### BACKGROUND

Conventional carrier substrates for surface emitting infrared light emitting diodes (IR-LEDs) are composed of Gallium Arsenide (GaAs), Germanium (Ge) or Silicon. GaAs and Ge substrates are potentially expensive and require additional processing steps to form on a surface emitting IR-LED.

### BRIEF DESCRIPTION OF THE DRAWINGS

A more detailed understanding can be had from the following description, given by way of example in conjunction with the accompanying drawings wherein:

FIG. 1 is a block diagram of an example device in which one or more features of the disclosure can be implemented;

FIG. 2 is a cross-section of a light-emitting film grown on a sacrificial semiconductor substrate, the light-emitting film having a random textured surface;

FIG. 3 shows the light-emitting film of FIG. 2 with a dielectric film, a metal film, and metal-semiconductor contact areas;

FIG. 4 is a cross-section of a conductive carrier including a substrate and a metal layer showing the formation of the conductive carrier including a substrate and a metal layer;

FIG. 5 is a cross-section of an optoelectronic semiconductor device according to an example embodiment; and

FIG. 6 is a flow diagram of an example method for manufacturing an optoelectronic semiconductor device according to an example embodiment.

### DETAILED DESCRIPTION

Although further detail will be provided below, briefly, an optoelectronic semiconductor device is described. More particularly, a light-emitting diode (LED), such as an infrared (IR) LED is described below.

The IR LED includes a top contact, a molybdenum conductive carrier, and a light-emitting film disposed between the top contact and the molybdenum conductive carrier. Additionally, a method for the manufacture of the optoelectronic semiconductor device is described below.

A conventional IR LED includes a Gallium Arsenide (GaAs) conductive substrate and is also based on semiconductor compounds such as Indium Phosphide (InP), Zinc Selenide (ZnSe), Gallium Nitride (GaN) and their ternary and quaternary compounds including In and Aluminum (Al). A common LED comprises a light-emitting region or light-emitting film grown on a semiconductor compound substrate, e.g. by means of Metal Organic Chemical Vapor Deposition (MOCVD), Liquid-Phase Epitaxy (LPE) or Molecular Beam Epitaxy (MBE) techniques. The light-emitting film includes a p-n junction (a boundary between a p-type semiconductor material and an n-type semiconductor material). Electrical current generated by two electrodes usually deposited on the bottom and top sides of the device flows through the p-n junction, generating photons whose wavelength depends on the specific semiconductor material. Light is emitted from the light-emitting film in all directions wherein light emitted towards the semiconductor substrate is absorbed by the semiconductor substrate.

A known method for decreasing such absorbance includes growing a thick “window layer” between the substrate and the light-emitting region, increasing the distance between the light-emitting region and the absorbing substrate, the window layer being transparent, absorbing only a minor fraction of the light transmitted through it. However, light emitted towards the substrate will still be absorbed by the substrate. Another known method includes the disposition of internal semiconductor reflection layers such as a Distributed Bragg Reflector (DBR) between the substrate and the light-emitting film. However, a DBR is only partially reflective. Thus, these known methods provide only a partial solution to the absorbing problem.

A further method for decreasing absorbance includes attaching the substrate with the grown light-emitting region to another semiconductor carrier which is fully transparent to the wavelength of the generated light. The attachment is done such that the original substrate material faces away from the carrier. The absorbing portion can then be removed, leaving behind only the light-emitting region attached to the transparent carrier. Light passing through the transparent carrier may be reflected (and directed) by the device packaging, where the device is attached onto a reflective material. However, this solution is complicated since perfect matching of different semiconductors types is problematic and difficult to achieve at low cost.

As used herein, the term “random texture” when referring to a face, surface, or interface is intended to mean that the face, surface, or interface is marked by non-symmetrical structures, including without limitation irregular projections containing inequalities, or ridges, including without limitation numerous and random edges or angles.

In addition, according to Snell's law, only those photons that reach the surface of the film at an angle lower than a critical angle for total reflection (defined by the respective refractive index of the materials at the interface) can exit the light-emitting film. In a three-dimensional view, the photons must reach the surface with an angle within a specific “exit cone” to escape from the light-emitting film. Other photons will be multiply reflected within the film until finally absorbed.

The random texture results in a diffuse reflection of light at the face of the light-emitting film or the lower layer facing the conductive carrier, randomly changing the travel directions of the photons. Thus, light subject to total reflection at the upper surface of the light-emitting film—the upper surface facing away from the conductive carrier and being provided for coupling out light from the device—will be reflected back to the upper surface via said face at random angles.

Therefore, the fraction of photons hitting the upper surface with an angle within the above-explained exit cone is increased. Light reflected from the textured surface back into the film is randomly distributed at different angles. Therefore, the light extraction efficiency of the optoelectronic semiconductor device is improved.

To further increase the light extraction efficiency, the light-emitting film or an upper layer disposed between the top contact and the light-emitting film may include an upper surface facing the top contact, the upper surface having a random surface texture. The light-emitting film and/or said upper layer may include at least one lateral surface, the at least one lateral surface having a random surface texture. Preferably, the upper layer is a window layer or current-spreading layer.

An optoelectronic semiconductor device includes a top contact and a conductive carrier including a metallic molybdenum conductive carrier substrate. A metal layer is deposited on the metallic molybdenum conductive carrier substrate. A light emitting film is disposed between the top contact, a mirror layer and the metallic molybdenum conductive carrier substrate.

The optoelectronic semiconductor device includes an upper surface disposed between the top contact and the light emitting film facing the top contact.

The optoelectronic semiconductor device includes a lateral surface on the light emitting film includes a lateral surface.

The optoelectronic semiconductor device includes the mirror system including a dielectric film.

The optoelectronic semiconductor device includes a dielectric film deposited upon an upper surface.

The optoelectronic semiconductor device includes the mirror system being formed by etching contact openings and depositing of contacts.

The optoelectronic semiconductor device includes the light emitting film included in a substrate layer.

The optoelectronic semiconductor device includes the metallic molybdenum conductive carrier substrate bonded to the substrate layer.

The optoelectronic semiconductor device includes a solder layer for bonding the metallic molybdenum conductive carrier substrate to the substrate layer.

The optoelectronic semiconductor device includes the top contact including electrodes.

A method of forming an optoelectronic semiconductor device includes depositing a first metal layer onto a metallic molybdenum conductive carrier substrate. A mirror system is formed on a gallium arsenide substrate layer. The first metal layer is bonded to a second metal layer. At least a portion of the gallium arsenide substrate layer is removed, and one or more electrodes is deposited.

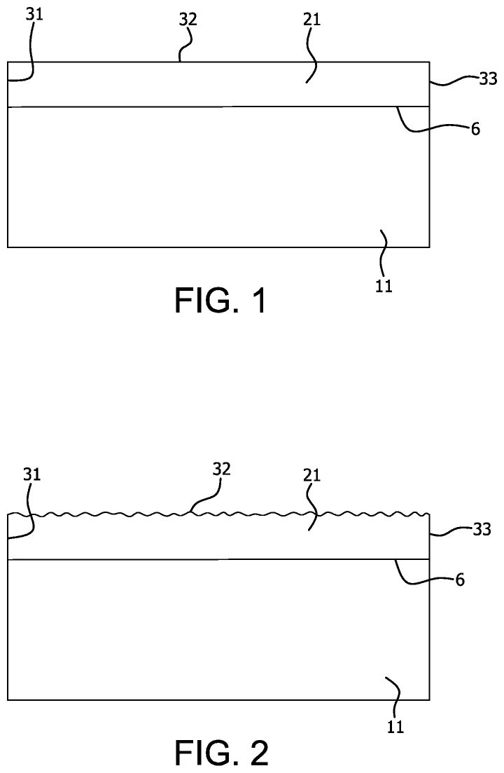

FIG. 1 shows a conventional chip. In a first step, a light-emitting film 21 having a thickness of typically 7 μm to 30 μm is grown on a GaAs substrate 11. The light-emitting film 21 includes an active (light-generating) layer (not shown), which may be an AlGaAs and semiconducting layers of types n and p (not shown). When current flows through the device, light is generated in film 21. The light which hits the compound-air interface at an angle outside the exit cone is reflected from surfaces 31, 32, and 33 of the light-emitting film 21. Moreover, light directed towards interface 6 which is disposed between the light-emitting film 21 and the substrate 11 is fully absorbed by the substrate 11.

The conventional chip as shown in FIG. 1 may be modified such that the surface 32 comprises a random surface texture as shown in FIG. 2. Surface texturing preferably is performed by treating the wafer in Hydrogen Fluoride (HF), Nitric Acid (HNO3) or other chemical etchants using conventional methods, and typically generates a random surface morphology having an average roughness of 5 nm (50 Å) to 70 nm (700 Å). Light reflected from the textured surface back into the film is randomly distributed at different angles. Therefore, this morphology increases the probability that light which hits the surface 32 will exit the light-emitting film 21 (hitting the surface 32 at an angle within the “exit cone”).

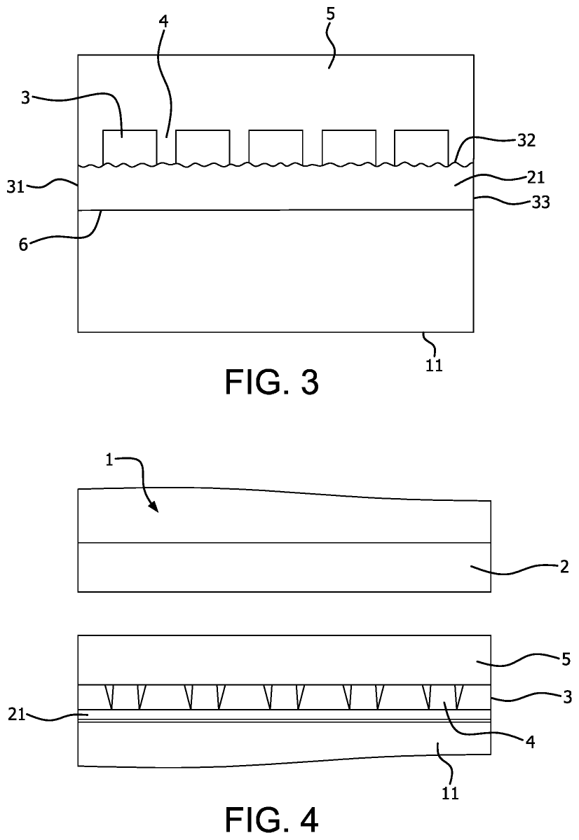

In a next step, a mirror film 3, 4, 5 is formed as shown in FIG. 3. It should be noted that the face of the mirror film 3, 4, 5 directed towards the light-emitting film 21 has a random texture complementary to the random texture of the surface 32 of the light-emitting film 21, i.e. the mirror film 3, 4, 5 and the light-emitting film 21 are in direct contact all over the surface 32. The mirror layer (e.g., film 3, 4, 5) reflects the light originating from layer 21 back into the LED.

For this purpose, a dielectric film 3 such as Silicon Dioxide (SiO₂) or Silicon Nitride (Si₃N₄) is deposited on top of textured surface 32 using conventional methods such as Plasma Enhanced Chemical Vapor Deposition (PECVD). The thickness of the dielectric film 3 is typically between 0.03 μm and 0.5 μm. Electrical current flow into the semiconductor material 21 requires definition of contact areas. This is accomplished by etching contact holes 4 in the dielectric film 3. The contact holes 4 having a contact diameter of typically 2 μm to 20 μm are created by a conventional lithography technique followed by either using a chemical etchant such as HF or using a plasma etch tool. Once the contact holes 4 are defined, a reflective metal 5 is deposited using a conventional metal deposition tool. Metal layer 5 may comprise Gold (Au) or Silver (Ag) in order to form a highly reflective mirror. Metal layer 5 includes a barrier metal for eliminating diffusion of material towards the semiconductor interface 32. A typical metal structure for a p-type contact would be an AuZn/TiW scheme with a total thickness of 0.1 μm to 0.5 μm. The combination of reflective metal layer 5 with a suitable dielectric layer 3 results in a highly reflective mirror. The textured pattern 32 covered by reflective mirror layer 3, 4, 5 provides a “diffuse mirror” which randomly reflects light generated in light-emitting film 21 in all directions.

The high reflectivity of the mirror ensures the high Light Output Power of the Surface emitting Diode in comparison with conventional LEDs. For example, even small changes in reflectivity (like between Ag and Au) can be visible.

FIG. 4 is a cross-section of the formation of the surface emitting diode comprising a conductive carrier substrate 1 and a metal layer 2 and the substrate 11 with the light emitting film 21 and the mirror system 3,4,5. The substrate 1 is a molybdenum substrate coated with a metal layer 2. Also shown in FIG. 4 is the portion of the components shown in FIG. 3 to which the molybdenum conductive carrier 1 and the metal layer 2 will be bonded. The metal layer 2 is deposited onto the conductive molybdenum wafer substrate 1. The metal layer 2 is a conventional metal electrode structure normally used for conductive substrates such as AuZn for p-type material or AuGe for n-type material having a thickness of typically 0.1 μm to 0.5 μm. On top of metal layer 2, another metal layer (not shown) having a thickness of typically 1 μm to 5 μm may be deposited which other metal layer comprises material needed for eutectic bonding such as AuSn.

The formation of the molybdenum conductive carrier 1 including the substrate and carrier wafer substrate 11/metal layer 5 is described herein. The mirror layer may be formed by etching of contact openings 4 and then deposition of the contacts (e.g., electrodes 12). This deposition may be performed by lifting off of unused area. A metal layer 5 (e.g., a solder layer) may be deposited for bonding.

The metal layer 2 is then bonded to the metal layer 5. The entire bonded substrate 11 with 21 and mirror system 3,4,5 and molybdenum conductive carrier 1 is rotated prior to formation of an optoelectronic semiconductor device. Once rotated, portions of the substrate 11 are removed.

More particularly, wet etching may be utilized to remove the substrate 11 in order to form a layer to deposit electrodes on, as described below.

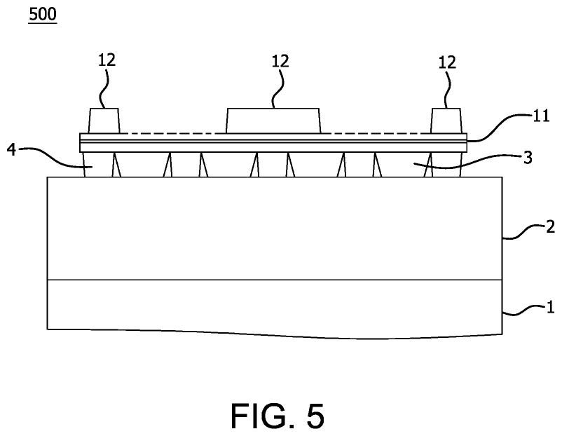

Wafer bonding is accomplished for example by using an eutectic bonding process. For this, the chip shown in FIG. 3 is flipped such that the GaAs substrate 11 is pointing upwards. With respect to the device shown in FIG. 4, the substrate 1 is the molybdenum conductive carrier substrate. The metal layer 5 of the chip of FIG. 3 and the metal layer 2 of the conductive carrier of FIG. 4 are then attached to each other as shown in FIG. 5. Wafer bonding is performed in a thermal oven in an inert atmosphere and by applying a controlled pressure on the combined chip.

Following wafer bonding, the light absorbing GaAs conductive substrate 11 is removed using conventional etching chemicals such as a Sulfuric Acid:Hydrogen Peroxide:Water (H₂SO₄:H₂O₂:H₂O) solution or a mechanical lapping technique. In a final step, top electrodes 12 are added using conventional techniques of lithography and metal electrode formation.

Additionally, a metallic layer may be added to the bottom of the device shown in FIG. 5. That is, a metallic backside layer may be added below carrier substrate 1.

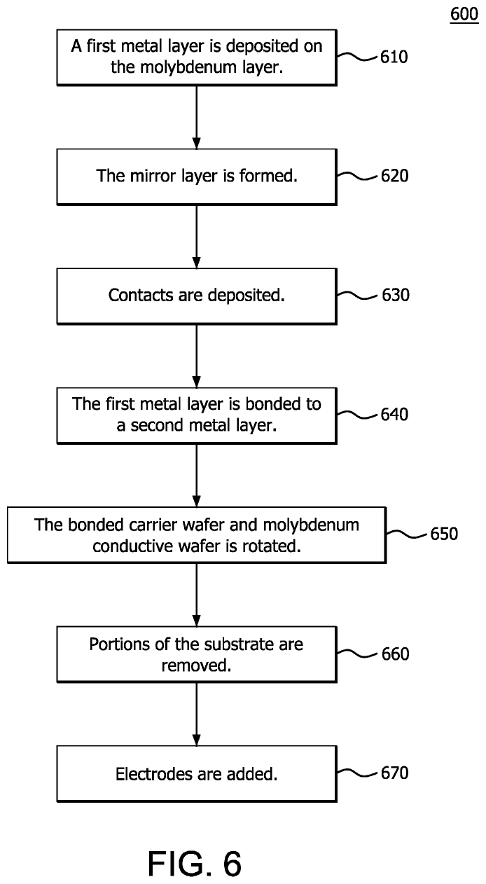

FIG. 6 is a flow diagram of an example method 600 for manufacturing an optoelectronic semiconductor device according to an example embodiment.

In step 610, a first metal layer is deposited on the molybdenum conductive carrier wafer 1. For example, referring back to FIGS. 4 and 5, the first metal layer may be metal layer 2 and a conventional metal electrode.

Next, the mirror layer above is formed (step 620) on the GaAs substrate 11 with light emitting area 21. This may be performed as described by etching of contact openings and depositing the contacts (step 630). The depositing step 630 may be performed by lifting off unused areas.

In step 640, the first metal layer is bonded to a second metal layer. Once bonded, the bonded carrier wafer containing substrate 11, light emitting area 21 and the mirror layer 3,4,5 and molybdenum conductive wafer are rotated for further processing (step 650).

At this point, portions of the substrate are removed (step 660). As described above, wet etching may be utilized to remove the conductive carrier substrate 11) in order to form a layer to deposit electrodes on. Again, this may be accomplished by utilizing a Sulfuric Acid:Hydrogen Peroxide:Water (H₂SO₄:H₂O₂:H₂O) solution or a mechanical lapping technique.

The electrodes are then deposited (step 670). For example, the electrodes may be added using conventional techniques of lithography and metal electrode formation.

It should be understood that many variations are possible based on the disclosure herein. Although features and elements are described above in particular combinations, each feature or element can be used alone without the other features and elements or in various combinations with or without other features and elements.

What is claimed is:

1. An optoelectronic semiconductor device, comprising:
a top contact;
a conductive carrier including a metallic molybdenum conductive carrier substrate;
a metal layer deposited on the metallic molybdenum conductive carrier substrate; and
a light emitting film, the light emitting film disposed between the top contact, a mirror system and the metallic molybdenum conductive carrier substrate.

2. The optoelectronic semiconductor device of claim 1, further comprising an upper surface disposed between the top contact and the light emitting film facing the top contact.

3. The optoelectronic semiconductor device of claim 1 wherein the light emitting film includes a lateral surface.

4. The optoelectronic semiconductor device of claim 1 wherein the mirror system includes a dielectric film.

5. The optoelectronic semiconductor device of claim 4 wherein the dielectric film is deposited upon an upper surface.

6. The optoelectronic semiconductor device of claim 1 wherein the mirror system is formed by etching contact openings and deposition of contacts.

7. The optoelectronic semiconductor device of claim 1 wherein the light emitting film is included in a substrate layer.

8. The optoelectronic semiconductor device of claim 1 wherein the metallic molybdenum conductive carrier substrate is bonded to the substrate layer.

9. The optoelectronic semiconductor device of claim 8, further comprising a solder layer for bonding the metallic molybdenum conductive carrier substrate to the substrate layer.

10. The optoelectronic semiconductor device of claim 1 wherein the top contact includes electrodes.

11. A method of forming an optoelectronic semiconductor device, the method comprising:
depositing a first metal layer onto a metallic molybdenum conductive carrier substrate;
forming a mirror system on a gallium arsenide substrate layer;
bonding the first metal layer to a second metal layer;
removing at least a portion of the gallium arsenide substrate layer; and
depositing one or more electrodes.

12. The method of claim 11, further comprising depositing a light emitting film between a top contact, the mirror layer and the metallic molybdenum conductive carrier substrate.

13. The method of claim 12 wherein the light emitting film includes a lateral surface.

14. The method of claim 11 wherein the mirror system includes a dielectric film.

15. The method of claim 14, further comprising depositing the dielectric film upon an upper surface.

16. The method of claim 11, further comprising forming the mirror layer by etching contact openings and deposition of contacts.

17. The method of claim 11 wherein the light emitting film is included in a substrate layer.

18. The method of claim 11, further comprising bonding the metallic molybdenum conductive carrier substrate to the gallium arsenide substrate layer.

19. The method of claim 18, further comprising depositing a solder layer for bonding the metallic molybdenum conductive carrier substrate to the gallium arsenide substrate layer.

20. The method of claim 11 wherein the electrodes are deposited via lithography.
